(19) United States
(12) Patent Application Publication
(10) Pub. No.: US 2024/0126939 A1
(43) Pub. Date: Apr. 18, 2024

(54) METHOD FOR DESIGNING MECHANICAL APPARATUS AND DEVICE USING THE SAME

(71) Applicant: CLEW INC., Seoul (KR)

(72) Inventors: JEONG GYU BAK, Seoul (KR); SEAWOOK LEE, Seoul (KR); MUN JIN CHO, Goyang-si (KR)

(21) Appl. No.: 18/300,208

(22) Filed: Apr. 13, 2023

(30) Foreign Application Priority Data
Oct. 14, 2022 (KR) 10-2022-0132586
Oct. 14, 2022 (KR) 10-2022-0132587

(51) Int. Cl. G06F 30/17

(52) U.S. Cl. CPC G06F 30/17

(57) ABSTRACT

There are provided a method for designing a mechanical apparatus and a device using the same. A method for acquiring shape information of a mechanical apparatus based on target performance information according to an embodiment may include: acquiring a first target performance parameter and a second target performance parameter of the mechanical apparatus; acquiring first shape information by using a first model based on the first target performance parameter and the second target performance parameter; acquiring a first prediction performance parameter by using a second model based on the first shape information; and updating the first model based on at least one of the first target performance parameter, the second target performance parameter or the first prediction performance parameter.

### CROSS-REFERENCE TO RELATED APPLICATION(S)

This application is based on and claims priority under 35 U.S.C. § 119 to Korean Patent Application No. 10-2022-0132586, filed on Oct. 14, 2022 and Korean Patent Application No. 10-2022-0132587, filed on Oct. 14, 2022 in the Korean Intellectual Property Office, the disclosure of which is herein incorporated by reference in its entirety.

### BACKGROUND

### Field

The disclosure relates to a method for designing a mechanical apparatus and a device using the same.

### Description of Related Art

Typically, programs used in engineering computations may require a higher level of education to be effectively used as they have many parameters and influence of the parameters on performance is complex. However, as communication technology and web technology have developed, an environment has been created in which programs can be distributed through a web browser without being installed in a computer and the distributed programs can be directly used, and an environment has been created in which parameters inputted by various users can be accumulated as data.

In addition, with the spread of portable communication devices such as smartphones or tablet PCs, efforts are ongoing to provide a service enabling relatively less experienced users to use an appropriate level of engineering computation by accumulating and utilizing experience of various users accustomed to engineering computations.

### SUMMARY

An object to be achieved by the disclosure is to provide a method for enabling a user who is not accustomed to engineering computations to smoothly perform a corresponding engineering computation, and providing a highly accurate result to the user.

The object to be achieved by the disclosure is not limited to that mentioned above, and other objects that are not mentioned above may be clearly understood to those skilled in the art based on the descriptions provided below and the accompanying drawings.

According to an embodiment, a method for acquiring shape information of a mechanical apparatus based on target performance information may include: acquiring a first target performance parameter and a second target performance parameter of the mechanical apparatus; acquiring first shape information by using a first model based on the first target performance parameter and the second target performance parameter; acquiring a first prediction performance parameter by using a second model based on the first shape information; and updating the first model based on at least one of the first target performance parameter, the second target performance parameter or the first prediction performance parameter.

The means for achieving the object of the disclosure is not limited to that mentioned above, and other solving means that are not mentioned above may be clearly understood to those skilled in the art based on the descriptions provided below and the accompanying drawings.

According to the disclosure, a user who is not accustomed to engineering computations can smoothly perform a corresponding engineering computation, and a highly accurate result can be provided to the user.

The effect of the disclosure is not limited to that mentioned above, and other effects that are not mentioned above may be clearly understood to those skilled in the art based on the descriptions provided below and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating an environment of a system according to an embodiment;

FIG. 2 is a block diagram illustrating a terminal according to an embodiment;

FIG. 3 is a block diagram illustrating a server according to an embodiment;

FIG. 4 is a block diagram regarding a method for acquiring shape information of a mechanical apparatus according to an embodiment;

FIG. 5 is a view provided to explain acquisition of a type of motor according to an embodiment;

FIG. 6 is a view provided to explain acquisition of a target performance parameter according to an embodiment;

FIG. 7 is a view provided to explain provision of shape information according to an embodiment;

FIG. 8 is a view provided to explain a modified design variable according to an embodiment;

FIG. 9 is a view provided to explain provision of a prediction performance parameter according to an embodiment;

FIG. 10 is a block diagram regarding a method for acquiring shape information of a mechanical apparatus according to another embodiment;

FIGS. 11 and 12 are views to explain updating of the first model according to an embodiment.

### DETAILED DESCRIPTION

Embodiments described in the specification are provided to clearly describe the technical concept of the disclosure for those of ordinary skill in the art, and the disclosure is not limited to the embodiments set forth in the specification, and the scope of the disclosure should be interpreted as including various modifications or changes without departing from the technical concept of the disclosure.

The terms used in the specification are general terms that are widely used by considering functions of the disclosure, but the terms may vary depending on intentions of those of ordinary skill in the art, precedents or advent of new technologies. However, if a term is defined as having a certain meaning and is used, the meaning of the term will be specified separately. Accordingly, the terms used in the specification should be interpreted not based on the names of the terms but based on substantial meanings of the terms and contents described throughout the specification.

The drawings attached with the specification are provided to assist in an easy explanation of the disclosure, and shapes illustrated in the drawings may be displayed in an exaggerated way for easy understanding of the disclosure if necessary, and the disclosure is not limited by the drawings.

In the specification, detailed descriptions of well-known configurations or functions will be omitted since they would unnecessarily obscure the subject matters of the disclosure.

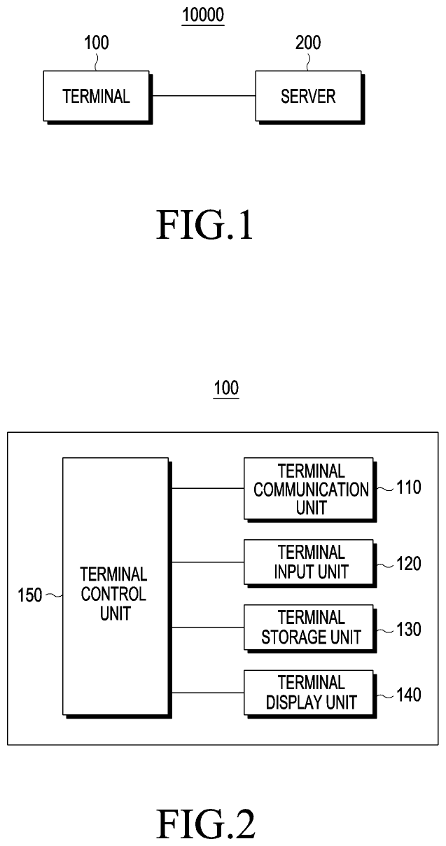

FIG. 1 is a view illustrating an environment of a system according to an embodiment.

Referring to FIG. 1, the system 10000 may include a terminal 100 and a server 200.

The terminal 100 may be implemented by a smartphone, a tablet personal computer (PC), a personal digital assistant (PDA), a laptop, a PC, a wearable device or the like.

In addition, an application may be provided in the terminal 100 to perform some embodiments which will be described below.

The server 200 may perform communication with the terminal 100 and may exchange a variety information with the terminal 100.

In an embodiment, at least one of the terminal 100 and the server 200 may include an engineering computation module. The engineering computation module may acquire a target performance parameter from a user and may provide shape information corresponding to the target performance parameter to the user based on the target performance parameter. In addition, the engineering computation module may include a first model and a second model which will be described below. The engineering computation module will be described in detail hereinbelow.

When the engineering computation module is included in the terminal 100, the engineering computation module may be driven in the terminal 100, and, when the engineering computation module is included in the server 200, the engineering computation module may be driven in the server 200.

In an embodiment, a device that drives the engineering computation module may be determined from the terminal 100 and the server 200 according to performance of the terminal 100.

Specifically, when the terminal 100 connects to the terminal 200 through a web browser, the server 200 may transmit a script file for evaluating a computation ability of the terminal 100 along with a webpage. The terminal 100 may provide the webpage obtained from the server 200 to the user, may execute the script file obtained from the server 200 and evaluate the computation ability of the terminal 100, and may transmit information regarding the computation ability, for example, performance information, to the server 200. Herein, the performance information may include a graphic computation ability, a CPU numeric value computation ability, a communication ability, and a memory ability.

In addition, the server 200 may evaluate the performance of the terminal 100 based on the performance information obtained from the terminal 100, according to a pre-set performance criterion required by applications. Herein, at least one of the applications may include an engineering computation module. In addition, at least one of the applications may be a computational analysis application.

In addition, the server 200 may determine whether the application is driven in the server 200 or the terminal 100, based on the result of evaluating the performance of the terminal 100. For example, when the performance of the terminal 100 exceeds a required performance criterion of the application as a result of evaluating the performance of the terminal 100, the server 200 may transmit the application to the terminal 100. In this case, the application may be a web assembly file which is executable in a web browser of the terminal 100 without having to be installed in the terminal 100.

In addition, when the performance of the terminal 100 does not exceed the required performance criterion of the application as a result of evaluating the performance of the terminal 100, the server 200 may not transmit the application to the terminal 100, and may drive the application in the server 200. For example, the server 200 may acquire input information of the application from the terminal 100, may input the input information to the application, and may acquire a result from the application. In addition, the server 200 may provide the result to the terminal 100. The terminal 100 may provide the result and/or the input information to the user.

In addition, the server 200 may periodically or aperiodically evaluate the computation ability of the terminal 100 even while the application is being driven in the terminal 100. In this case, when the performance of the terminal 100 does not exceed the required performance criterion of the application, the server 200 may acquire input information and/or an intermediate result from the terminal 100, and may acquire a result by using the application based on the input information and/or the intermediate result.

In addition, a plurality of applications may be driven in the server 200. In this case, when it is predicted that the server 200 lacks a computation ability as the plurality of applications are driven, and the performance of the terminal 100 does not exceed a required performance criterion of a specific application, the server 200 may not directly execute the specific application and may register the specific application at a scheduler. Thereafter, when the computation ability of the server 200 is guaranteed, the server 200 may execute the specific application by executing applications registered at the scheduler in sequence.

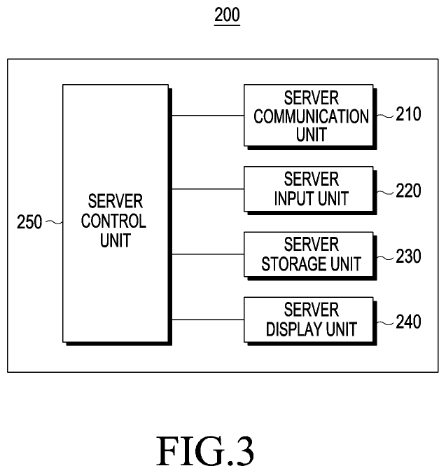

FIG. 2 is a block diagram of the terminal according to an embodiment.

Referring to FIG. 2, the terminal 100 may include a terminal communication unit 110, a terminal input unit 120, a terminal storage unit 130, a terminal display unit 140, and a terminal control unit 150.

The terminal communication unit 110 may perform communication with the server 200. In addition, the terminal communication unit 110 may include a mobile communication module to support Bluetooth low energy (BLE), Bluetooth, wireless local area network (WLAN), wireless fidelity (WiFi), WiFi Direct, near field communication (NFC), infrared data association (IrDA), ultra wide band (UWB), Zigbee, 3G, 4G, or 5G, and a wired or wireless module to transmit data according to various other communication standards.

The terminal input unit 120 may acquire a signal corresponding to an input of a user. In addition, the terminal input unit 120 may acquire an input (for example, a target performance parameter) for acquiring information necessary for engineering computations. In addition, the terminal input unit 120 may be implemented by, for example, a keyboard, a keypad, a touch pad, a button, a jog shuttle, a wheel, etc. In addition, the input of the user may be, for example, pressing a button, touching, dragging, etc. When the terminal display unit 140 is implemented by a touch screen, the terminal display unit 140 may perform a role of the terminal input unit 120.

In addition, the terminal storage unit 130 may store various data. For example, the terminal storage unit 130 may store data necessary for operations of the terminal 100 (for example, information necessary for engineering computations, an engineering computation module, and an application including the engineering computation module).

The terminal storage unit 130 may include at least one type of storage medium of a flash memory type, a hard disk type, a multimedia card micro type, a memory of a card type (for example, an SD or XD memory, etc.), a random access memory (RAM), a static RAM (SRAM), a read-only memory (ROM), an electrically erasable programmable read-only memory (EEPROM), a programmable read-only memory (PROM) magnetic memory, a magnetic disk, an optical disk. In addition, the memory may store information temporarily, permanently, or semi-permanently, and may be provided in an embedded type or a detachable type.

The terminal display unit 140 may output a variety of visual information. For example, the terminal display unit 140 may output various applications, input information inputted to the various applications, an output provided from an application, etc. In addition, the terminal display unit 140 may output information received from the server 200 and/or information to provide to the server 200. The terminal display unit 140 may be a liquid crystal display (LCD), an organic light emitting diode (OLED), an active-matrix OLED (AMOLED) display, or the like. When the terminal display unit 140 is provided as a touch screen, the terminal display unit 140 may perform a function of the terminal input unit 120. In this case, a separate terminal input unit 120 may not be provided according to a selection, and a terminal input unit 120 performing a restricted function, such as volume control, a power button, and a home button, may be provided.

The terminal control unit 150 may control the respective components of the terminal 100 or may process and compute a variety of information. In addition, the terminal control unit 150 may acquire signals from some components included in the terminal 100. In addition, the terminal control unit 150 may control operations for performing some steps performed in the terminal 100 among the steps of methods, which will be described below, or may perform computations necessary for performing steps. In an embodiment, the terminal control unit 150 may include an engineering computation module.

The terminal control unit 150 may be implemented by software, hardware, and a combination of these. For example, in terms of hardware, the terminal control unit 150 may be implemented by a field programmable gate array (FPGA) or an application specific integrated circuit (ASIC), a semiconductor chip, and electronic circuits of various types. In another example, in terms of software, the terminal control unit 150 may be implemented by a logic program or various computer languages performed according to the above-described hardware.

The terminal 100 may not necessarily include all of the above-described components, and some components may be omitted according to a selection. In addition, the terminal 100 may have a component added to perform an additional function and operation according to a selection.

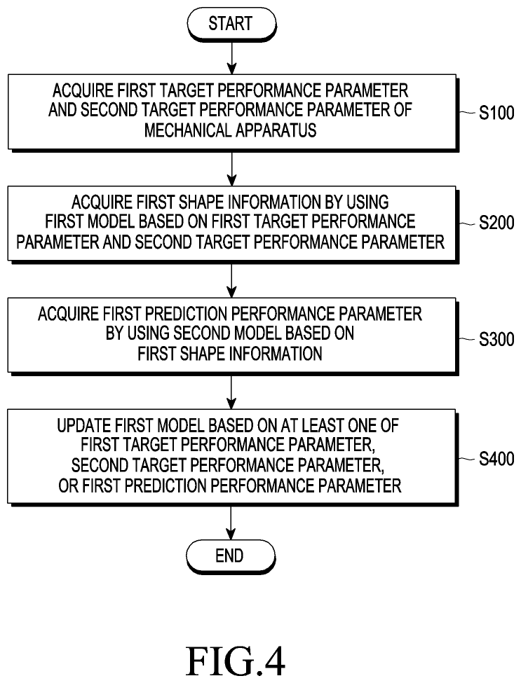

FIG. 3 is a block diagram of the server according to an embodiment.

Referring to FIG. 3, the server 200 may include a server communication unit 210, a server input unit 220, a server storage unit 230, a server display unit 240, and a server control unit 250.

The server communication unit 210 may perform communication with the terminal 100. In addition, the server communication unit 210 may include a mobile communication module to support BLE, Bluetooth, WLAN, WiFi, WiFi Direct, NFC, IrDA, UWB, Zigbee, 3G, 4G, or 5G, and a wired or wireless module to transmit data according to various other communication standards.

The server input unit 220 may acquire a signal corresponding to an input of a user. In addition, the server input unit 220 may include a keyboard, a keypad, a touch pad, a button, a jog shuttle, a wheel, etc.

The server storage unit 230 may store various data. For example, the server storage unit 230 may include data (for example, a plurality of applications, performance information required by each of the plurality of applications, a script file for evaluating a computation ability of the terminal 100, an engineering calculation module, etc.) necessary for operations of the server 200 and/or the terminal 100.

In addition, the server storage unit 230 may include at least one type of storage medium of a flash memory type, a hard disk type, a multimedia card micro type, a memory of a card type (for example, an SD or XD memory, etc.), a RAM, an SRA), a ROM, an EEPROM, a PROM magnetic memory, a magnetic disk, an optical disk. In addition, the memory may store information temporarily, permanently, or semi-permanently, and may be provided in an embedded type or a detachable type.

In addition, the server display unit 240 may output a variety of visual information. For example, the server display unit 240 may be an LCD, an OLED, an AMOLED display, or the like.

In addition, the server control unit 250 may control the respective components of the server 200 or may process and compute a variety of information. In addition, for example, the server control unit 250 may include an engineering computation module. In addition, the server control unit 250 may control operations for performing some steps performed in the server 200 among the steps of methods, which will be described below, or may perform computations necessary for performing steps.

The server control unit 250 may be implemented by software, hardware, and a combination of these. For example, in terms of hardware, the server control unit 250 may be implemented by a FPGA or an ASIC, a semiconductor chip, and electronic circuits of various types. In another example, in terms of software, the server control unit 250 may be implemented by a logic program or various computer languages performed according to the above-described hardware.

The server 200 may not necessarily include all of the above-described components, and some components may be omitted according to a selection. For example, when the server 200 does not provide direct visual information, the sever 200 may be provided without the server display unit 240. In addition, the server 200 may have a component added to perform an additional function and operation according to a selection.

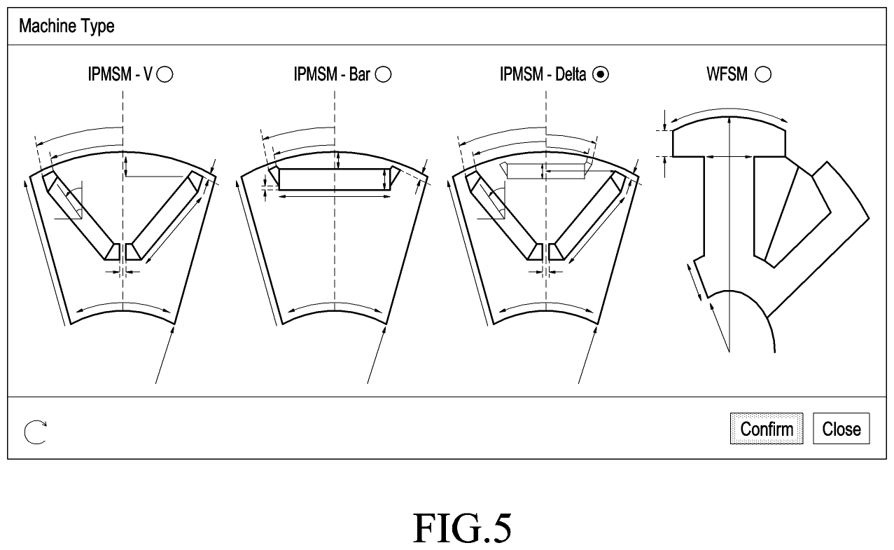

FIG. 4 is a block diagram regarding a method for acquiring shape information of a mechanical apparatus according to an embodiment.

Referring to FIG. 4, the method for acquiring the shape information of the mechanical apparatus according to an embodiment may include a step of acquiring a first target performance parameter and a second target performance parameter of the mechanical apparatus (S100), a step of acquiring first shape information by using a first model based on the first target performance parameter and the second target performance parameter (S200), a step of acquiring a first prediction performance parameter by using a second model based on the first shape information (S300), and a step of updating the first model based on at least one of the first target performance parameter, the second target performance parameter or the first prediction performance parameter.

The method for acquiring the shape information of the mechanical apparatus according to an embodiment may be performed in an engineering computation module, and the engineering computation module may be included in the terminal or the server. Although it will be explained hereinbelow that the method for acquiring the shape information of the mechanical apparatus according to the embodiment is performed in the engineering computation module for convenience of explanation, this should not be considered as limiting. The method for acquiring the shape information of the mechanical apparatus according to the embodiment may be substantially performed in the terminal or the server including the engineering computation module. In other words, operations of the engineering computation module in the disclosure may be understood as operations of the terminal or the server including the engineering computation module.

At step S100, the engineering computation module may acquire the first target performance parameter and the second target performance parameter of the mechanical apparatus. For example, the terminal may receive input of the first target performance parameter and the second target performance parameter of the mechanical apparatus from a user, and may transmit the inputted first target performance parameter and second target performance parameter of the mechanical apparatus to the server.

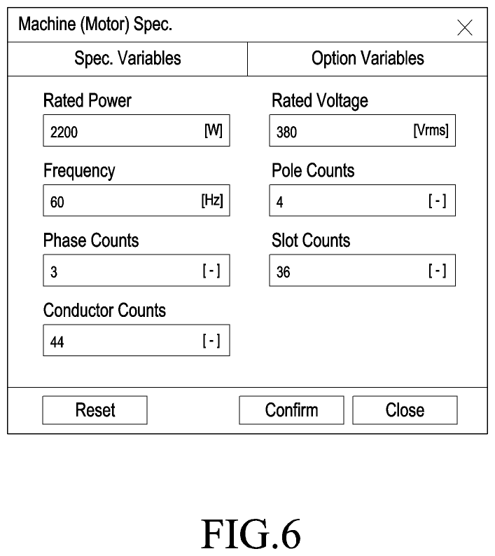

Specifically, the engineering computation module may acquire information regarding the type of the mechanical apparatus. Herein, the mechanical apparatus may include a mechanical component. For example, the mechanical apparatus may include a motor, and the server may include information regarding a type of motor (for example, an induction motor, a permanent magnet synchronous motor, a synchronous reluctance motor (SynMR), etc.). For example, the engineering computation module may visually output the information regarding the type of motor as shown in FIG. 5, and may receive a selection of at least one of the outputted motors from the user. In addition, the terminal may provide information regarding the selected type of motor to the server. For convenience of explanation, the mechanical apparatus will be referred to as a motor, but this should not be considered as limiting. It should be noted that mechanical apparatuses other than the motor are included in the right scope of the disclosure.

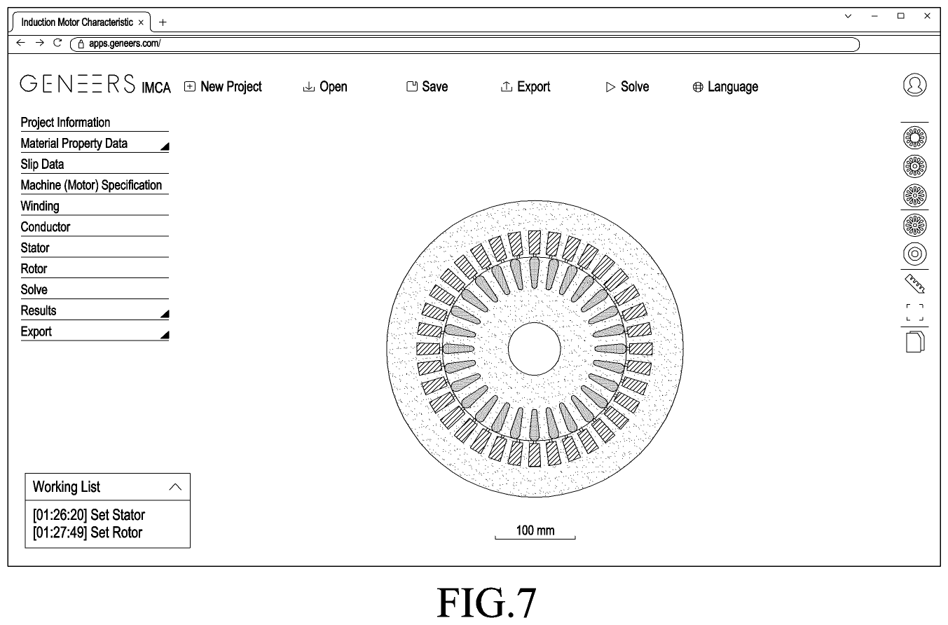

In addition, the engineering computation module may acquire the first target performance parameter and the second target performance parameter from the terminal. For example, the engineering computation module may visually output information regarding a target performance parameter through the terminal as shown in FIG. 6, and may receive an input of a numerical value regarding at least one piece of information of the outputted information of the target performance parameter. Herein, the target performance parameter may be information that is necessary for acquiring shape information (for example, a drawing) of the selected type of mechanical apparatus, and the engineering computation module may provide a shape capable of achieving target performance of the target performance parameter. In addition, the target performance parameter may include a design condition or design information. For example, when the mechanical apparatus is a motor, the target performance parameter may include a target output of the motor, efficiency, a frequency of input power (operating speed), an operating temperature, a voltage of input power, the number of phases, the number of slots, the number of motors, the number of poles, a wiring method, etc. In addition, the target performance parameter may include information regarding a material of the motor. In addition, the target performance parameter may include shape information of a stator or a rotor (that is, target shape information), a filler factor, a current density, winding information, etc.

In addition, in an embodiment, the target performance parameter may be divided into the first target performance parameter and the second target performance parameter. Herein, the first target performance parameter may refer to a parameter that is inputted to the first model, which will be described below, and the second target performance parameter may refer to a parameter that is inputted to the first model and the second model, which will be described below. For example, when the mechanical apparatus is a motor, the second target performance parameter may include at least one of a torque, efficiency, an operating temperature, a frequency of input power, a voltage of input power, material information, electromagnetic filed information such as a magnetic flux density in the motor, at least one piece of mechanical performance information (for example, a saturation temperature, volume information, weight information, material property information, etc.), and electrical performance information. In addition, the first target performance parameter may include parameters except for the second target performance parameters among the above-described target performance parameters.

At step S200, the engineering computation module may acquire the first shape information by using the first model based on the first target performance parameter and the second target performance parameter.

In an embodiment, the engineering computation module may input the first target performance parameter and the second target performance parameter to the first model, and may output the first shape information from the first model. Herein, the first model may include a design variable and design information corresponding to the first target performance parameter and the second target performance parameter.

In addition, the first model may be configured by a reduced order model (ROM) or a machine learning model. Herein, the reduced order model may refer to a simplified mathematical modeling technique for solving the problem of inefficiency in computing time caused by complexity of the mathematical model and a high degree of freedom. For example, basically, the reduced order model may derive a result only from a range requiring analysis in a frequency domain. For example, the reduced order model may reduce the order of a governing equation. In general, a governing equation of a system having a high degree of freedom may be formed of high-order mass and stiffness matrixes. In a process of analyzing such a system, an inverse matrix may be calculated, causing a lot of computation loads and inefficient analysis. To solve this, the reduced order model may select only a mode requiring analysis in order to reduce the burden of computation, and may reduce the order of the governing equation as much as the number of selected modes, by reflecting physical coordinates on modal coordinates. In addition, the reduced order model may be a model in which a relationship between a design variable and prediction performance information is mathematically configured. Herein, the design variable may indicate numerical value information of respective components of the mechanical apparatus, such as a size of a coil, an area of the coil, etc. In addition, in an embodiment, the reduced order model may be configured by an ordinary differential equation.

In addition, the machine learning model may be configured by various algorithms such as k-nearest neighbors (kNN), linear regression, logistic regression, support vector machines (SVC), decision trees, random forests, artificial neural networks, etc.

Hereinafter, it will be explained that the first model is a reduced order model for convenience of explanation, but this should not be considered as limiting, and the first model may be configured by a machine learning model.

In addition, the first model may include a database. The database may store a target performance parameter and corresponding shape design information which match each other. In addition, a relationship between the target performance parameter and the corresponding shape design information may be established through kriging or a mathematical algorithm which is able to constitute a meta model such as a machine learning model.

The engineering computation module may acquire the first shape information based on at least one of the reduced order model (or the machine learning model) and the database. In an embodiment, the first shape information may include design information and a design variable (that is, a numerical value of a design variable) of the mechanical apparatus. Herein, the design variable may be determined by an engineering mathematical formula. For example, in the case of a coil, the engineering computation module may compute an area of the coil as a design variable. In addition, the design information indicates a design of the mechanical apparatus, and for example, in the case of a coil, the design information may indicate a design of the coil having the corresponding area. The engineering computation module may acquire the design variable by using the reduced order model, may acquire the design information by using the database, and may acquire the first shape information by using the acquired design variable and design information.

The engineering computation module may acquire the first shape information by using any one of the reduced order model (or machine learning model) or the database. For example, the engineering computation module may acquire the design variable by using the reduced order model, and may acquire the first shape information by acquiring the design information based on the design variable. In addition, the engineering computation module may acquire the first shape information corresponding to the first target performance parameter and the second target performance parameter from the database.

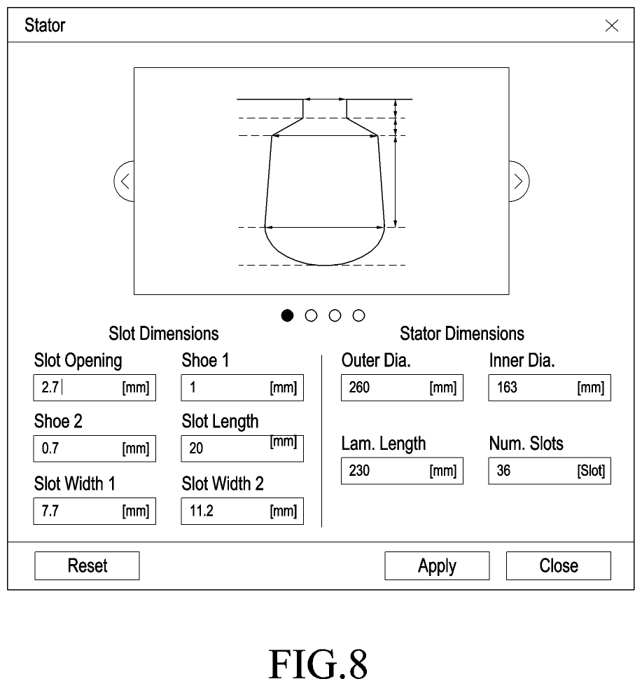

In addition, the engineering computation module may provide the first shape information to the user through the terminal. For example, the engineering computation module may display the first shape information through the terminal as shown in FIG. 7.

In addition, at step S300, the engineering computation module may acquire the first prediction performance parameter by using the second model based on the first shape information. In an embodiment, the engineering computation module may input the first shape information to the second model, and may acquire the first prediction performance parameter from the second model. Herein, the second model may predict detailed performance more exactly by simulating pre-defined shape information under a given condition. For example, the second model may be a finite element analyzer or may be an experimental value. In addition, the first prediction performance parameter may refer to detailed performance that is predicted from the first shape information. That is, when the engineering computation module receives a target performance parameter from a user, the engineering computation module may acquire the first shape information based on the target performance parameter through the first model, and may acquire the first prediction performance parameter based on the first shape information through the second model. That is, simply by inputting a target performance parameter to the engineering computation module, a user may acquire not only shape information but also a target performance parameter corresponding to the shape information from the engineering computation module, and accordingly, there is an effect that highly accurate shape information can be easily acquired.

In addition, the engineering computation module may input the second target performance parameter to the second model along with the first shape information.

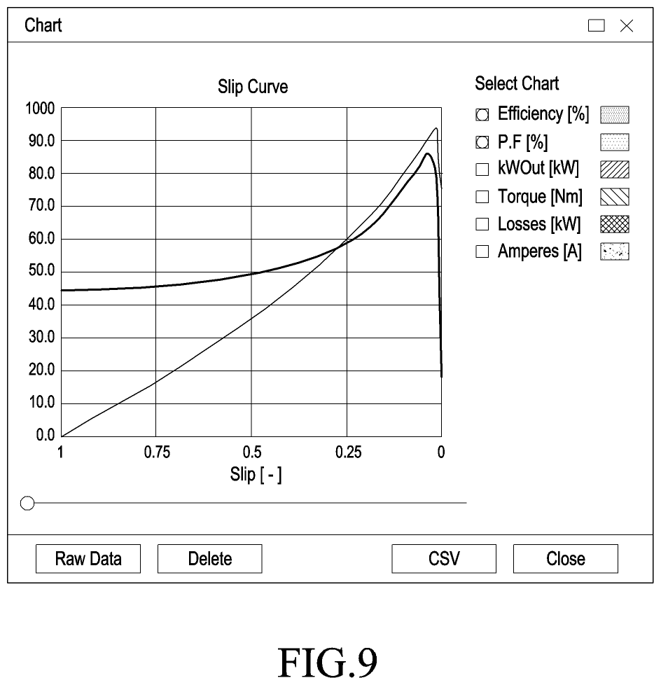

In addition, the engineering computation module may input a modified design variable that is modified by the user to the second model. In a specific example, the engineering computation module may provide the design variable of the first shape information while visually outputting the first shape information through the terminal as shown in FIG. 8. In addition, the engineering computation module may acquire a modified design variable regarding the design variable. In this case, the engineering computation module may input the modified design variable to the first model and may output second shape information indicating the modified shape information. In addition, the engineering computation module may input a modified parameter and/or the second shape information to the second model, and may acquire a second prediction performance parameter indicating a modified prediction performance parameter.

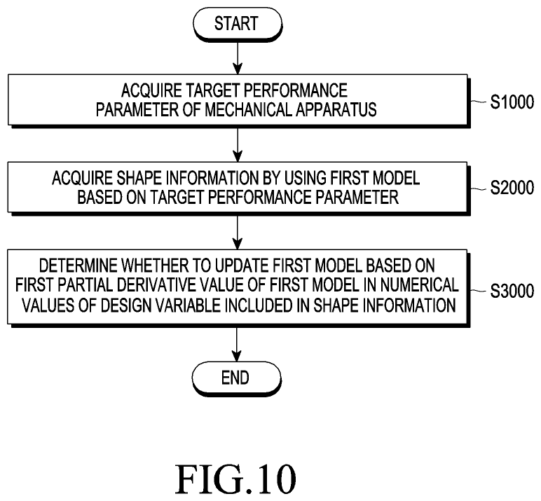

In addition, the engineering computation module may visually output the first prediction performance parameter or the second prediction performance parameter as shown in FIG. 9.

In addition, at step S400, the engineering computation module may update the first model based on at least one of the first target performance parameter, the second target performance parameter or the first prediction performance parameter.

Specifically, the engineering computation module may compare the first prediction performance parameter (and/or the second prediction performance parameter) acquired at step S300, and the first target performance parameter and the second target performance parameter acquired at step S100. When a difference between the first prediction performance parameter (and/or the second prediction performance parameter) and the first/second target performance parameter is greater than or equal to a predetermined ratio (for example, 5%) as a result of comparing, the engineering computation module may replace a parameter that overlaps the first prediction performance parameter (and/or the second prediction performance parameter) among the first/second target performance parameters with the first prediction performance parameter (and/or the second prediction performance parameter), and may update the first model based on a parameter that does not overlap the first prediction performance parameter (and/or the second prediction performance parameter) among the first/second target performance parameters, the first prediction performance parameter (and/or the second prediction performance parameter), and the first shape information. That is, when an output value of the second model and an input value of the first model are different by a predetermined ratio or more, the first model may be updated based on the output value of the second model, and, accordingly, accuracy of the first model may be enhanced.

On the other hand, when the difference between the first prediction performance parameter (and/or the second prediction performance parameter) and the first/second target performance parameter is less than the predetermined ratio (for example, 5%), the first prediction performance parameter (and/or the second prediction performance parameter) may not be used for updating the first model.

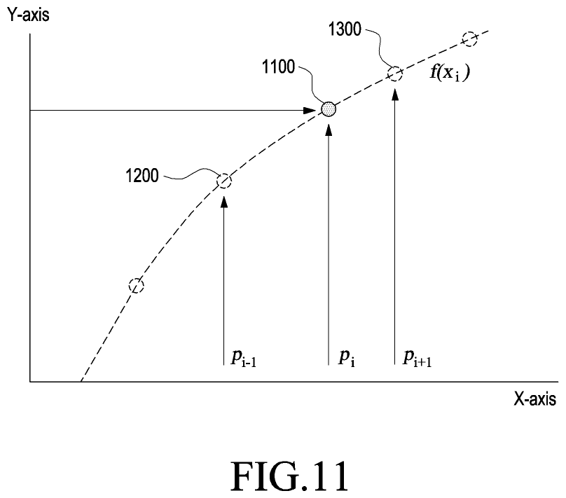

FIG. 10 is a block diagram regarding a method for acquiring shape information of a mechanical apparatus according to another embodiment.

Referring to FIG. 10, the method for acquiring the shape information of the mechanical apparatus according to another embodiment may include a step of acquiring a target performance parameter of the mechanical apparatus (S1000), a step of acquiring shape information by using a first model based on the target performance parameter (S2000), and a step of determining whether to update the first model based on a first partial derivative value of the first model in numerical values of a design variable included in the shape information (S3000).

At step S1000, the target performance parameter may include the first target performance parameter and the second target performance parameter of step S100 described above. Contents explained at step S100 described above may be applied to step S1000, and a detailed description is omitted.

At step S2000, the shape information may include the first shape information and the second shape information of step S200 described above. Contents explained at step S200 described above may be applied to step S2000, and a detailed description is omitted.

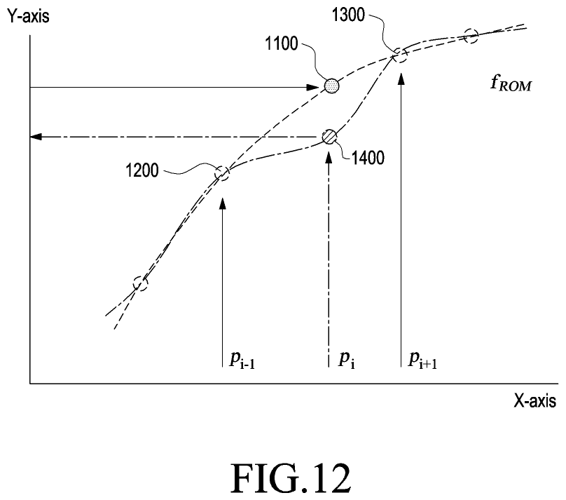

At step S3000, the engineering computation module may determine whether to update the first model based on a first partial derivative value of the first model in numerical values of the design variable included in the shape information. Step S3000 will be described with reference to FIGS. 11 and 12.

FIGS. 11 and 12 are views to explain updating of the first model according to an embodiment.

Referring to FIGS. 11 and 12, the X-axis in graphs of FIGS. 11 and 12 may indicate a design variable and the Y-axis may indicate a prediction performance parameter. In an embodiment, the reduced order model may include an equation f(x1, x2, x3, . . . , xn). Herein, x1, x2, x3, . . . , xn indicate respective design variables (shape dimension information, a voltage, etc.), and a resulting value of f(x1, x2, x3, . . . , xn) may indicate a prediction performance parameter. In addition, the dotted line in the graphs of FIGS. 11 and 12 may indicate f(xi) indicating a prediction performance parameter of xi which is one of the design variables. In addition, dotted circles in the graphs of FIGS. 11 and 12 may indicate data that has been verified. That is, in the graph of FIG. 11, a first neighboring prediction performance parameter 1200 and a second neighboring prediction performance parameter 1300 are verified data, and the first neighboring prediction performance parameter 1200 may indicate a prediction performance parameter corresponding to a numerical value pi−1 of the design variable xi, and the second neighboring prediction performance parameter 1300 may indicate a prediction performance parameter corresponding to a numerical value pi+1 of the design variable xi. The first neighboring prediction performance parameter 1200 and the second neighboring prediction performance parameter 1300 may be stored in the first model.

In an embodiment, the engineering computation module may acquire a numerical value pi of the design variable along with a target performance parameter 1100 and shape information corresponding to the target performance parameter 110 through steps S1000 to S2000.

Specifically, the engineering computation module may acquire the numerical value pi of the design variable xi corresponding to the target performance parameter 1100 by using the first model. In this case, the target performance parameter 1100 may be data that has not yet been verified, and the numerical value pi of the design variable xi corresponding to the target performance parameter 1100 may also be data that has not yet been verified. In order to enhance accuracy, the engineering computation module may determine accuracy of the numerical value pi of the design variable xi and the target performance parameter 1100 by using the numerical value pi−1 of the design variable xi, the numerical value pi+1 of the design variable xi, the first neighboring prediction performance parameter 1200 and the second neighboring prediction performance parameter 1300 which have been verified. More specifically, the engineering computation module may compute a first partial derivative value which is a partial derivative value of the reduced order model at the numerical value pi of the design variable xi. That is, the engineering computation module may compute a partial derivative value of the equation f(xi) at the numerical value pi of the design variable xi as the first partial derivative value. In addition, the engineering computation module may acquire the numerical value pi−1 which is smaller than the numerical value pi of the design variable xi, and the first neighboring prediction performance parameter 1200. The numerical value pi−1 and the first neighboring prediction performance parameter 1200 may be pre-stored in the engineering computation module, and may be computed based on the first model. In addition, the engineering computation module may compute a second partial derivative value which is a partial derivative value at the numerical value pi−1, based on the numerical value pi−1, the first neighboring prediction performance parameter 1200, the numerical value pi of the design variable xi, and the target performance parameter 1100. For example, the engineering computation module may compute the second partial derivative value by dividing a difference value between the target performance parameter 1100 and the first neighboring prediction performance parameter 1200 by a difference value between the numerical value pi and the numerical value pi−1 of the design variable xi.

In addition, when a difference between the first partial derivative value and the second partial derivative value is greater than or equal to a predetermined ratio (for example, 5%), the engineering computation module may acquire a prediction performance parameter by using the second model based on the shape information. Regarding this, contents explained at step S300 of FIG. 3 described above may be applied, and a detailed description is omitted.

In addition, when the difference between the first partial derivative value and the second partial derivative value is greater than or equal to the predetermined ratio (for example, 5%), the engineering computation module may determine to update the first model. As shown in the graph of FIG. 12, the engineering computation module may replace the target performance parameter 1100 with a prediction performance parameter 1400, and may update the first model based on the prediction performance parameter 1400 and the numerical value pi of the design variable. Accordingly, the updated first model may be changed as indicated by the dash-single dotted line of the graph of FIG. 12.

In addition, when the difference between the first partial derivative value and the second partial derivative value is less than the predetermined ratio (for example, 5%), the engineering computation module may acquire the numerical value pi+1 which is larger than the numerical value pi of the design variable xi, and the second neighboring prediction performance parameter 1300. The numerical value pi+1 and the second neighboring prediction performance parameter 1300 may be pre-stored in the engineering computation module, and may be computed based on the first model. In addition, the engineering computation module may compute a third partial derivative value which is a partial derivative value at the numerical value pi+1, based on the numerical value pi+1, the second neighboring prediction performance parameter 1300, the numerical value pi of the design variable xi, and the target performance parameter 1100. For example, the engineering computation module may compute the third partial derivative value by dividing a difference value between the second neighboring prediction performance parameter 1300 and the target performance parameter 1100 by a difference value between the numerical value pi+1 and the numerical value pi of the design variable xi.

In addition, when a difference between the first partial derivative value and the third partial derivative value is greater than or equal to a predetermined ratio (for example, 5%), the engineering computation module may acquire a prediction performance parameter by using the second model based on the shape information. Regarding this, contents explained at step S300 of FIG. 3 described above may be applied, and a detailed description is omitted.

In addition, when the difference between the first partial derivative value and the third partial derivative value is greater than or equal to the predetermined ratio (for example, 5%), the engineering computation module may determine to update the first model. As shown in the graph of FIG. 12, the engineering computation module may replace the target performance parameter 1100 with the prediction performance parameter 1400, and may update the first model based on the prediction performance parameter 1400 and the numerical value pi of the design variable. Accordingly, the updated first model may be changed as indicated by the dash-single dotted line of the graph of FIG. 12.

In addition, when the difference between the first partial derivative value and the third partial derivative value is less than the predetermined ratio (for example, 5%), the engineering computation module may determine not to update the first model.

In an embodiment, it is explained that the engineering computation module computes the second partial derivative value, first, and then, computes the third partial derivative value at step S300, but this should not be considered as limiting. The engineering computation module may compute the third partial derivative value, first, and then, may compute the second partial derivative value.

Although embodiments have been described with reference to specified embodiments and drawings as described above, various modifications and changes may be made from the above descriptions by a person skilled in the art. For example, even when the above-described technologies are performed in a different order from that described above, and/or components of the above-described system, structure, device, circuit, etc. are coupled or combined in different forms from that described above, or are replaced or substituted with other components or equivalents, appropriate results may be achieved.

Therefore, other implementations, other embodiments, and equivalents to the scope of the claims belong to the scope of the claims presented below.

What is claimed is:

1. A method for acquiring shape information of a mechanical apparatus based on target performance information, the method comprising:
acquiring first target performance parameter and second target performance parameter of the mechanical apparatus;
acquiring first shape information by using first model based on the first target performance parameter and the second target performance parameter;
acquiring first prediction performance parameter by using second model based on the first shape information; and
updating the first model based on at least one of the first target performance parameter, the second target performance parameter or the first prediction performance parameter.

2. The method of claim 1, wherein updating the first model comprises:
comparing the first target performance parameter and the first prediction performance parameter;
when a difference between the first target performance parameter and the first prediction performance parameter is greater than or equal to a predetermined ratio, replacing a parameter that overlaps the first prediction performance parameter among the first target performance parameter and the second target performance parameter with the first prediction performance parameter;
updating the first model based on a parameter that does not overlap the first prediction performance parameter among the first target performance parameter and the second target performance parameter, the first prediction performance parameter and the first shape information.

3. The method of claim 1, wherein updating the first model comprises, when a difference between the first target performance parameter and the first prediction performance parameter is less than a predetermined ratio, updating the first model without using the first prediction performance parameter.

4. The method of claim 1, wherein, when the mechanical apparatus is a motor, the first target performance parameter comprises at least one of a type of the motor, an output, a number of poles, a frequency, a voltage, an operating temperature, or efficiency.

5. The method of claim 4, wherein the first target performance parameter further comprises target shape information of the mechanical apparatus, a number of slots, winding information, a fill factor, or a current density.

6. The method of claim 1, wherein, when the mechanical apparatus is a motor, the second target performance parameter comprises at least one of material information of the motor, a saturation temperature, volume information, weight information, or material property information.

7. The method of claim 1, wherein acquiring the first prediction performance parameter by using the second model based on the first shape information comprises inputting the first shape information to the second model and acquiring the first prediction performance parameter from the second model.

8. The method of claim 7, wherein acquiring the first prediction performance parameter by using the second model based on the first shape information comprises additionally inputting the second target performance parameter to the second model and acquiring the first prediction parameter from the second model.

9. The method of claim 1, further comprising:
providing the first shape information; and
acquiring second shape information based on the first shape information,
wherein acquiring the first prediction performance parameter comprises inputting the second shape information to the second model and acquiring the first prediction performance parameter from the second model.

10. A non-transitory computer-readable recording medium having recorded thereon a program for performing the method of claim 1.

11. A device for acquiring shape information of a mechanical apparatus based on target performance information, the device comprising an engineering computation module,
wherein the engineering computation module is configured to:
acquire first target performance parameter and second target performance parameter of the mechanical apparatus;
acquire first shape information by using first model based on the first target performance parameter and the second target performance parameter;
acquire first prediction performance parameter by using second model based on the first shape information; and
update the first model based on at least one of the first target performance parameter, the second target performance parameter or the first prediction performance parameter.
